(19) United States
(12) Patent Application Publication
(10) Pub. No.: US 2026/0114270 A1
(43) Pub. Date: Apr. 23, 2026

(54) SEMICONDUCTOR DEVICE

(71) Applicant: Mitsubishi Electric Corporation, Tokyo (JP)

(72) Inventor: Ayanori GATTO, Tokyo (JP)

(73) Assignee: Mitsubishi Electric Corporation, Tokyo (JP)

(21) Appl. No.: 19/282,387

(22) Filed: Jul. 28, 2025

(30) Foreign Application Priority Data
Oct. 18, 2024 (JP) 2024-184176

(51) Int. Cl. H01L 23/482

(52) U.S. Cl. CPC H10W 20/484

(57) ABSTRACT

A semiconductor device includes: a semiconductor substrate in which an active region and a termination region are defined; a first gate pad arranged at the center of a first side of the active region; a first gate wiring connected to the first gate pad and extending in a first direction; first gate signal lines connected to the first gate pad or the first gate wiring and extending in a second direction; a second gate pad arranged at a corner of the first side of the active region; a second gate wiring connected to the second gate pad and having a portion extending in the first direction; and second gate signal lines connected to the second gate pad or the second gate wiring and extending in the second direction. The second gate wiring extends along a boundary between the active region and the termination region.

### BACKGROUND OF THE INVENTION

### Field of the Invention

The present disclosure relates to a semiconductor device.

### Description of the Background Art

For example, in a conventional semiconductor device described in Japanese Patent Application Laid-Open No. 2010-109545 or the like, an active region in which a semiconductor element is formed, a gate pad arrangement region formed at a position adjacent to the active region, and a termination region, which is a region outside the active region and the gate pad arrangement region, are defined on a semiconductor substrate. A first gate pad is arranged at one end of the gate pad arrangement region in a first direction, and a first gate wiring extending in a second direction, which is a direction intersecting the first direction, is connected to the first gate pad. A second gate pad is arranged at the other end of the gate pad arrangement region in the first direction, and a second gate wiring extending in the second direction is connected to the second gate pad. Further, a first gate signal line extending in the first direction is connected to the first gate wiring, and a second gate signal line extending in the first direction is connected to the second gate wiring.

However, since the first and second gate signal lines are not arranged in the gate pad arrangement region defined in the conventional semiconductor device and an output current does not flow, the gate pad arrangement region becomes an ineffective region. Thus, since the effective area of the conventional semiconductor device is small, there is a problem that the on-resistance increases and the conduction loss increases.

Further, the first and second gate pads, the first and second gate wirings, and the first and second gate signal lines have a comb shape in a top view. Since the first and second gate signal lines extend from one end to the other end of the active region in the first direction, gate resistances of the first and second gate signal lines increase. As a result, there is a problem that delays of gate signals from the first and second gate pads to ends of the first and second gate signal lines increase.

### SUMMARY

An object of the present disclosure is to provide a technique capable of expanding the effective area of a semiconductor device and reducing a delay of a gate signal.

A semiconductor device according to the present disclosure includes a semiconductor substrate, a first gate pad, a first gate wiring, a first gate signal line, a second gate pad, a second gate wiring, and a second gate signal line. In the semiconductor substrate, an active region in which a semiconductor element is formed, the active region having a quadrangular shape in a top view, and a termination region, which is a region outside the active region, are defined. The first gate pad is arranged at a center of a first side of the active region. The first gate wiring is connected to the first gate pad and extends in a first direction. The first gate signal line is connected to the first gate pad or the first gate wiring, and extends in a second direction that is a direction intersecting the first direction. The second gate pad is arranged at a corner of the first side of the active region. The second gate wiring is connected to the second gate pad and has a portion extending in the first direction. The second gate signal line is connected to the second gate pad or the second gate wiring, and extends in the second direction. The second gate wiring extends along a boundary between the active region and the termination region.

Since the first and second gate pads are arranged in the active region and the first and second gate signal lines are also arranged between the first gate pad and the second gate pad, an output current also flows between the first gate pad and the second gate pad, so that a region between the first gate pad and the second gate pad also becomes an effective region. Thus, the effective region of the semiconductor device is expanded.

Further, since the first gate pad is arranged at the center of the first side of the active region and the second gate pad is arranged at the corner of the first side of the active region, lengths of the first and second gate signal lines arranged between the first gate pad and the second gate pad are shorter than those in a case where the first and second gate signal lines extend from one end to the other end of the active region in the first direction. As a result, gate resistances of the first and second gate signal line decrease, and it is possible to reduce delays of gate signals from the first and second gate pads to ends of the first and second gate signal lines.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematic top view for describing each region defined in a semiconductor substrate included in a semiconductor device according to a first preferred embodiment;

FIG. 2 is a schematic top view of the semiconductor device according to the first preferred embodiment;

FIG. 3 is an enlarged view corresponding to a region A of FIG. 2 in a modification of the first preferred embodiment;

FIG. 4 is an enlarged view of a region B of FIG. 2;

FIG. 5 is a schematic top view of a semiconductor device according to a second preferred embodiment;

FIG. 6 is an enlarged view of a region C of FIG. 5;

FIG. 7 is a schematic top view of a semiconductor device according to a modification of the second preferred embodiment; and

FIG. 8 is a schematic top view of a semiconductor device according to the related art.

### DESCRIPTION OF THE PREFERRED EMBODIMENTS

### First Preferred Embodiment

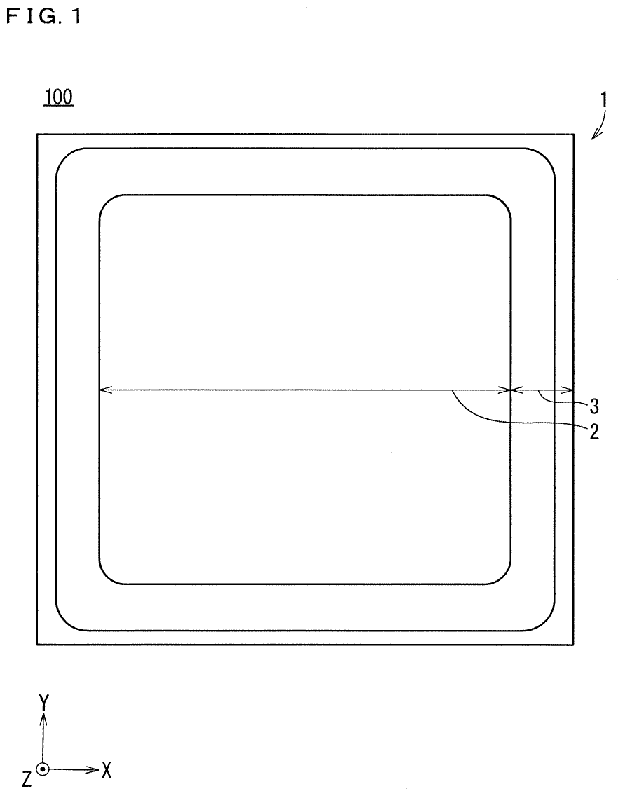

A first preferred embodiment will be described below with reference to the drawings. FIG. 1 is a schematic top view for describing each region defined in a semiconductor substrate 1 included in a semiconductor device 100 according to the first preferred embodiment.

In FIG. 1, an X direction, a Y direction, and a Z direction are orthogonal to each other. The X direction, the Y direction, and the Z direction illustrated in the following drawings are also orthogonal to each other. Hereinafter, a direction including the X direction and a direction (−X direction) opposite to the X direction is also referred to as a “X-axis direction”. Hereinafter, a direction including the Y direction and a direction (−Y direction) opposite to the Y direction is also referred to as a “Y-axis direction”. Hereinafter, a direction including the Z direction and a direction (−Z direction) opposite to the Z direction is also referred to as a “Z-axis direction”.

As illustrated in FIG. 1, a semiconductor device 100 includes the semiconductor substrate 1. In the semiconductor substrate 1, an active region 2 and a termination region 3 are defined. The active region 2 is a region where a semiconductor element (not illustrated) is formed. The active region 2 is formed in a quadrangular shape in the top view, and an outline of the active region 2 in the top view includes a side in the-Y direction (corresponding to a first side), a side in the Y direction (corresponding to a second side), a side in the-X direction (corresponding to a third side), and a side in the X direction (corresponding to a fourth side). The termination region 3 is a region outside the active region 2, in other words, a region outside the first side, the second side, the third side, and the fourth side, and is formed in a frame shape.

Here, the semiconductor element is an insulated gate bipolar transistor (IGBT), a metal oxide semiconductor field effect transistor (MOSFET), or the like.

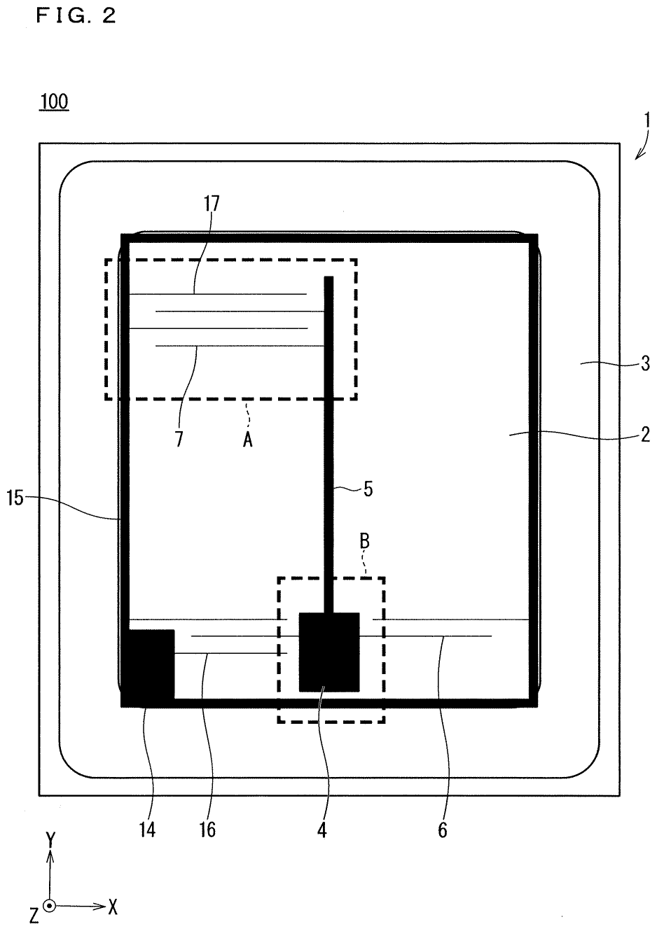

Next, details of the semiconductor device 100 will be described. FIG. 2 is a schematic top view of the semiconductor device 100 according to the first preferred embodiment. As illustrated in FIG. 2, the semiconductor device 100 further includes a first gate pad 4, a first gate wiring 5, first gate signal lines 6 and 7, a second gate pad 14, a second gate wiring 15, and second gate signal lines 16 and 17.

The first gate pad 4 is arranged at the center of the side in the-Y direction of the active region 2. The first gate wiring 5 is connected to the first gate pad 4 and extends from the first gate pad 4 to the vicinity of the side in the Y direction of the active region 2 in the Y-axis direction (corresponding to a first direction). The first gate signal line 6 is connected to the first gate pad 4 and extends in the X-axis direction (corresponding to a second direction) that is a direction intersecting the Y direction. The first gate signal line 7 is connected to the first gate wiring 5, and extends in the X-axis direction.

The second gate pad 14 is arranged at a corner of the side in the −Y direction of the active region 2. The corner of the side in the −Y direction of the active region 2 is a connection portion of the active region 2 between the side in the −Y direction and the side in the −X direction or the side in the X direction. The second gate pad 14 is arranged at a corner in the −X direction in FIG. 2, but may be arranged at a corner in the X direction instead. The second gate wiring 15 is connected to the second gate pad 14, has a portion extending in the Y-axis direction, and extends along a boundary between the active region 2 and the termination region 3. In other words, the second gate wiring 15 extends along the side in the −X direction, the side in the Y direction, the side in the X direction, and the side in the −Y direction of the active region 2. The second gate signal line 16 is connected to the second gate pad 14 and extends in the X-axis direction. The second gate signal line 17 is connected to the second gate wiring 15, and extends in the X-axis direction.

All of the first gate pad 4, the first gate wiring 5, the second gate pad 14, and the second gate wiring 15 include a polysilicon thin film and a metal thin film. With this configuration, it is possible to reduce gate resistances connected between the first gate pad 4 and the first gate wiring 5 and between the second gate pad 14 and the second gate wiring 15. Although not illustrated, gate resistors may be built in between the first gate pad 4 and the first gate wiring 5 and between the second gate pad 14 and the second gate wiring 15, respectively.

The first gate signal line 6 and the second gate signal line 16 are alternately arranged in the Y-axis direction between the first gate pad 4 and the second gate pad 14 and between the first gate pad 4 and the second gate wiring 15. The first gate signal line 7 and the second gate signal line 17 are alternately arranged in the Y-axis direction between the first gate wiring 5 and a portion of the second gate wiring 15 extending along the side in the −X direction.

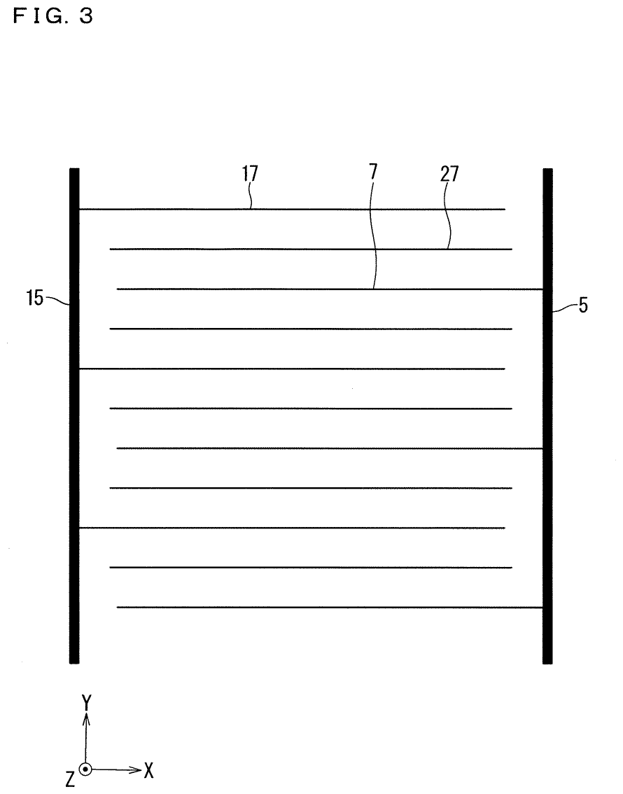

FIG. 3 is an enlarged view corresponding to a region A of FIG. 2 in a modification of the first preferred embodiment. As illustrated in FIG. 3, a dummy gate signal line 27 may be arranged between the first gate signal line 7 and the second gate signal line 17, which are arranged between first gate wiring 5 and the portion of the second gate wiring 15 extending along the side in the −X direction. The dummy gate signal line 27 is connected to an emitter electrode (ground potential) which is not illustrated.

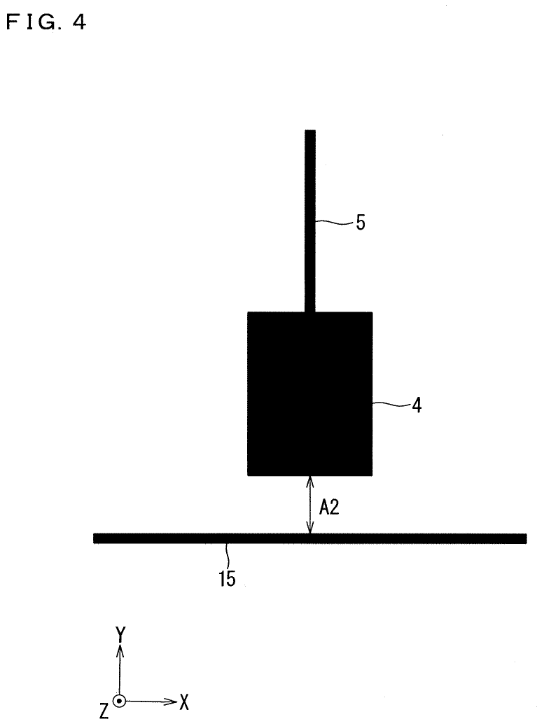

FIG. 4 is an enlarged view of a region B of FIG. 2. As illustrated in FIG. 4, an interval A2 between the first gate pad 4 and the second gate wiring 15 is 10 μm or more. This is to suppress interference between a gate signal flowing through the first gate pad 4 and a gate signal flowing through the second gate wiring 15.

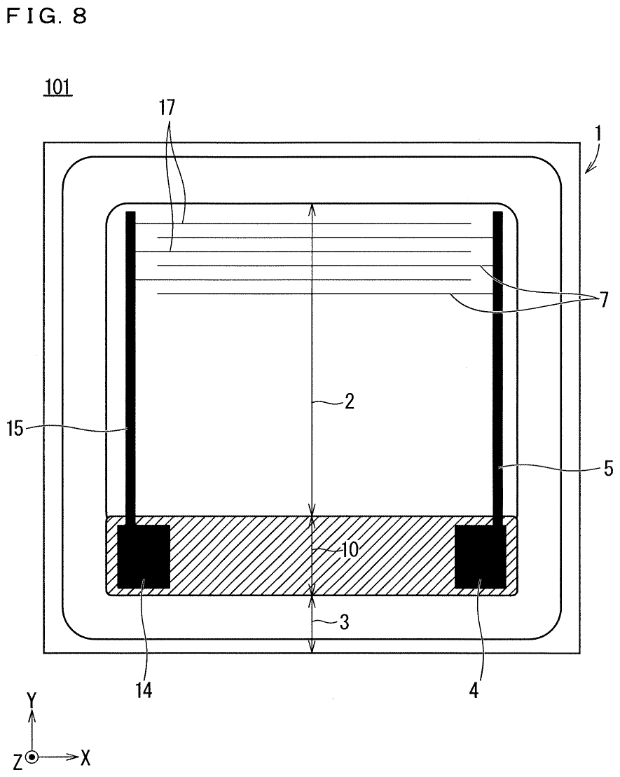

Next, functions and effects of the first preferred embodiment will be described in comparison with the related art. FIG. 8 is a schematic top view of a semiconductor device 101 according to the related art.

As illustrated in FIG. 8, in a semiconductor device 101 according to the related art, the active region 2, a gate pad arrangement region 10 formed at a position adjacent to the active region 2, and the termination region 3, which is a region outside the active region 2 and the gate pad arrangement region 10, are defined in the semiconductor substrate 1. The first gate pad 4 is arranged at an end of the gate pad arrangement region 10 in the X direction, and the first gate wiring 5 extending in the Y-axis direction is connected to the first gate pad 4. The second gate pad 14 is arranged at an end of the gate pad arrangement region 10 in the −X direction, and the second gate wiring 15 extending in the Y-axis direction is connected to the second gate pad 14. Further, the first gate signal line 7 extending in the X-axis direction is connected to the first gate wiring 5, and the second gate signal line 17 extending in the X-axis direction is connected to the second gate wiring 15.

Since the first and second gate signal lines 7 and 17 are not arranged in the gate pad arrangement region 10 and an output current does not flow, the gate pad arrangement region 10 becomes an ineffective region. Thus, the effective area of the semiconductor device 101 is small, and thus there is a problem that the on-resistance increases and a conduction loss increases.

On the other hand, as illustrated in FIG. 2, in the first preferred embodiment, the semiconductor device 100 includes: the semiconductor substrate 1 in which the active region 2 in which the semiconductor element is formed, the active region having the quadrangular shape in the top view and the termination region 3 which is the region outside the active region 2 are defined; the first gate pad 4 arranged at the center of the side in the −Y direction of the active region 2; the first gate wiring 5 connected to the first gate pad 4 and extending in the Y-axis direction; the first gate signal lines 6 and 7 connected to the first gate pad 4 or the first gate wiring 5 and extending in the X-axis direction that is the direction intersecting the Y-axis direction; the second gate pad 14 arranged at the corner of the side in the-Y direction of the active region 2; the second gate wiring 15 connected to the second gate pad 14 and having the portion extending in the Y-axis direction; and the second gate signal lines 16 and 17 connected to the second gate pad 14 or the second gate wiring 15 and extending in the X-axis direction. The second gate wiring 15 extends along the boundary between the active region 2 and the termination region 3.

Therefore, since the first and second gate pads 4 and 14 are arranged in the active region 2 and the first and second gate signal lines 6 and 16 are also arranged between the first gate pad 4 and the second gate pad 14, a cell structure of the semiconductor element can be arranged in a region where the first and second gate signal lines 6 and 16 are arranged, and an output current also flows between the first gate pad 4 and the second gate pad 14. As a result, a region between the first gate pad 4 and the second gate pad 14 also becomes an effective region. Thus, the effective region of the semiconductor device 100 is expanded. Since the effective region of the semiconductor device 100 is expanded, a conduction voltage of the semiconductor element at the same output current decreases, and a conduction loss can be reduced.

Next, an effect of reducing a delay of a gate signal will be described. When a trench is formed in the active region 2 and the semiconductor element is a trench IGBT, each of the first and second gate wirings 5 and 15 includes a polysilicon thin film. Each of the first and second gate wirings 5 and 15 may also include a polysilicon thin film and a metal thin film.

On the other hand, each of the first and second gate signal lines 6, 7, 16, and 17 includes a polysilicon thin film embedded in a trench. However, in a case where the dummy gate signal line 27 is arranged, the dummy gate signal line 27 also includes a polysilicon thin film embedded in a trench. The polysilicon thin films forming the first and second gate wirings 5 and 15 and the polysilicon thin films forming the first and second gate signal lines 6, 7, 16, and 17 are formed in the same polysilicon deposition process and have the same resistivity. Since the cross-sectional area of the polysilicon thin film forming each of the first and second gate wirings 5 and 15 is much larger than the cross-sectional area of the polysilicon thin film forming each of the first and second gate signal lines 6, 7, 16, and 17, the resistance per unit length of each of the first and second gate wirings 5 and 15 is small. Note that the cross-sectional area of a general gate wiring is 10² μm², and the cross-sectional area of a general gate signal line is 5 μm² or more and 6 μm² or less.

When each of the first and second gate wirings 5 and 15 includes the polysilicon thin film and the metal thin film, the resistance further decreases. That is, with respect to a delay of a gate signal, resistance components of the first and second gate signal lines 6, 7, 16, and 17 are dominant over resistance components of the first and second gate wirings 5 and 15. As illustrated in FIG. 2, the second gate wiring 15 has a closed loop shape, but the resistance components of the first and second gate signal lines 6, 7, 16, and 17 are dominant as described above since the resistance component of the second gate wiring 15 is relatively small even if the second gate wiring 15 does not have the closed loop shape. Thus, when the following delay is considered, only the first and second gate signal lines 6, 7, 16, and 17 are approximately focused.

As illustrated in FIG. 8, in the semiconductor device 101 according to the related art, the first and second gate pads 4 and 14, the first and second gate wirings 5 and 15, and the first and second gate signal lines 7 and 17 have a comb shape in the top view. Since the first and second gate signal lines 7 and 17 extend from one end to the other end of the active region 2 in the X-axis direction, gate resistances of the first and second gate signal lines 7 and 17 increase. As a result, delays of gate signals from the first and second gate pads 4 and 14 to ends of the first and second gate signal lines 7 and 17 increase. That is, this is a delay difference in the same gate signal line. Further, due to this delay in the gate signal line, a delay difference in a gate signal also occurs between the first gate signal line 7 close to the first gate wiring 5 and the second gate signal line 17 close to the second gate wiring 15. That is, this is a delay difference between the first gate signal line 7 and the second gate signal line 17.

On the other hand, in the semiconductor device 100 according to the first preferred embodiment, the first gate pad 4 is arranged at the center of the side in the −Y direction of the active region 2 and the second gate pad 14 is arranged at the corner of the side in the −Y direction of the active region 2 as illustrated in FIG. 2. Thus, lengths of the first and second gate signal lines 6 and 16 arranged between the first gate pad 4 and the second gate pad 14 are shorter than those in a case where the first and second gate signal lines 6 and 16 extend from one end to the other end of the active region 2 in the X-axis direction. As a result, gate resistances of the first and second gate signal lines 6 and 16 decrease, and it is possible to reduce delays of gate signals from the first and second gate pads 4 and 14 to ends of the first and second gate signal lines 6 and 16. With this configuration, it is possible to reduce not only a delay difference in the same gate signal line but also a delay difference between the first gate signal line 6 and the second gate signal line 16.

In addition, since the first gate signal lines 6 and 7 are arranged alternately with the second gate signal lines 16 and 17, respectively, in the Y-axis direction, a carrier concentration control effect caused by a double gate operation can be made uniform.

In a case where the dummy gate signal line 27 is arranged between the first gate signal line 7 and the second gate signal line 17, a conducting current does not flow in a region where dummy gate signal line 27 is arranged, so that the output current of semiconductor device 100 can be suppressed.

Since each of the first gate pad 4, the first gate wiring 5, the second gate pad 14, and the second gate wiring 15 includes the polysilicon thin film and the metal thin film, it is possible to reduce gate resistors connected between the first gate pad 4 and the first gate wiring 5 and between the second gate pad 14 and the second gate wiring 15.

### Second Preferred Embodiment

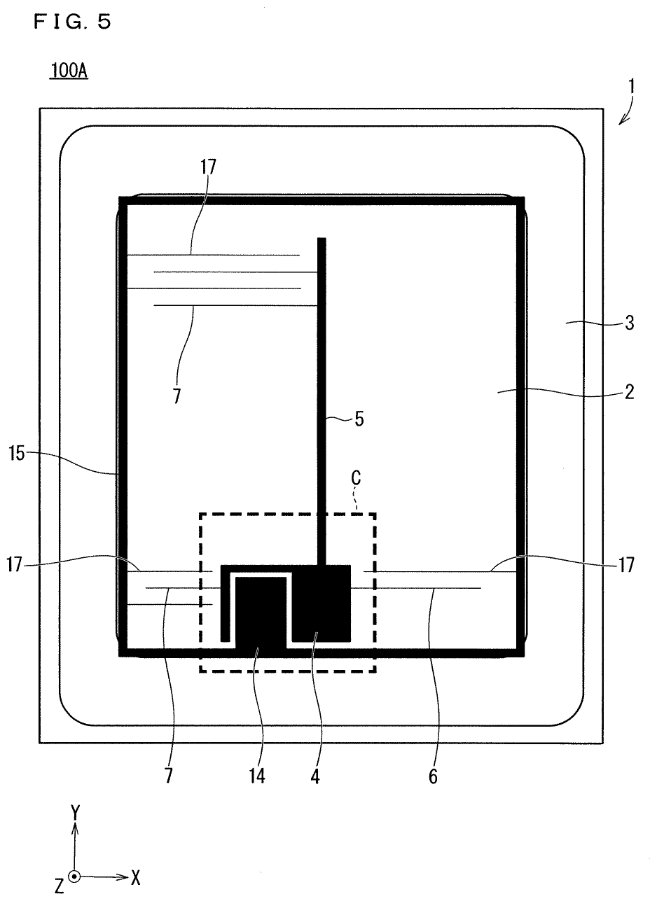

Next, a second preferred embodiment will be described. FIG. 5 is a schematic top view of a semiconductor device 100A according to the second preferred embodiment. In the second preferred embodiment, the same components as those described in the first preferred embodiment are denoted by the same reference signs, and description thereof is omitted.

As illustrated in FIG. 5, in the second preferred embodiment, an arrangement position of the second gate pad 14 and a shape of the first gate wiring 5 are different from those in the first preferred embodiment.

The first gate pad 4 is arranged at the center of the side in the-Y direction of the active region 2. The second gate pad 14 is arranged at a position adjacent to the first gate pad 4 at the center of the side in the-Y direction of the active region 2. In FIG. 5, the second gate pad 14 is arranged in the-X direction of the first gate pad 4, but may be arranged in the X direction of the first gate pad 4.

The first gate wiring 5 is connected to the first gate pad 4 and has a portion extending from the first gate pad 4 to the vicinity of a side in the Y direction of the active region 2 in the Y-axis direction and a portion partially surrounding the outer periphery of the second gate pad 14 in the Y direction and the −X direction. The first gate signal line 6 is connected to the first gate pad 4 and extends in the X-axis direction that is a direction intersecting the Y-axis direction. The first gate signal line 7 is connected to the first gate wiring 5, and extends in the X-axis direction.

The second gate wiring 15 is connected to the second gate pad 14, has a portion extending in the Y-axis direction, and extends along a boundary between the active region 2 and the termination region 3. In other words, the second gate wiring 15 extends along the side in the −X direction, the side in the Y direction, the side in the X direction, and the side in the −Y direction of the active region 2. The second gate signal line 17 is connected to the second gate wiring 15, and extends in the X-axis direction. In the second preferred embodiment, the second gate signal line 16 connected to the second gate pad 14 is not arranged.

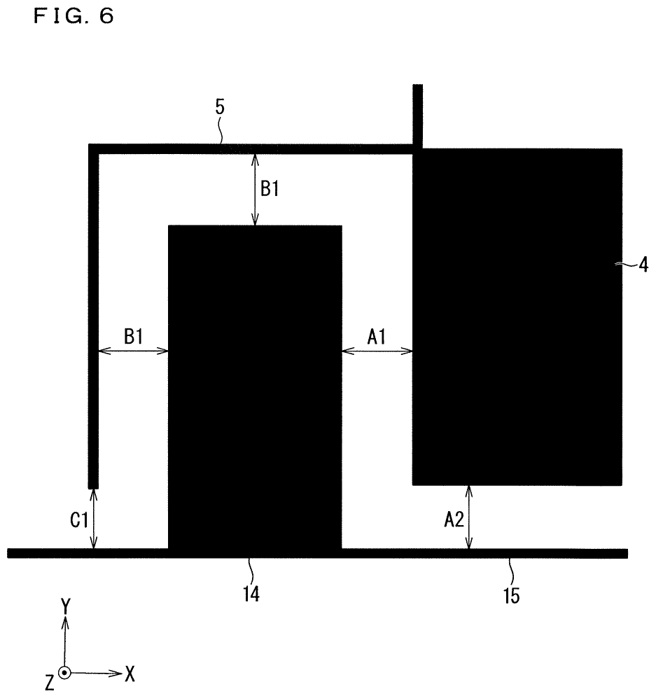

FIG. 6 is an enlarged view of a region C in FIG. 5. As illustrated in FIG. 6, an interval A1 between the first gate pad 4 and the second gate pad 14, the interval A2 between the first gate pad 4 and the second gate wiring 15, an interval B1 between the second gate pad 14 and the first gate wiring 5, and an interval C1 between the first gate wiring 5 and the second gate wiring 15 are all 10 μm or more. This is to suppress interference between gate signals flowing through the respective portions. Note that the interval A1, the interval B1, and the interval C1 are 10 μm or more also in the first preferred embodiment although intervals other than the interval A2 are not mentioned in the first preferred embodiment.

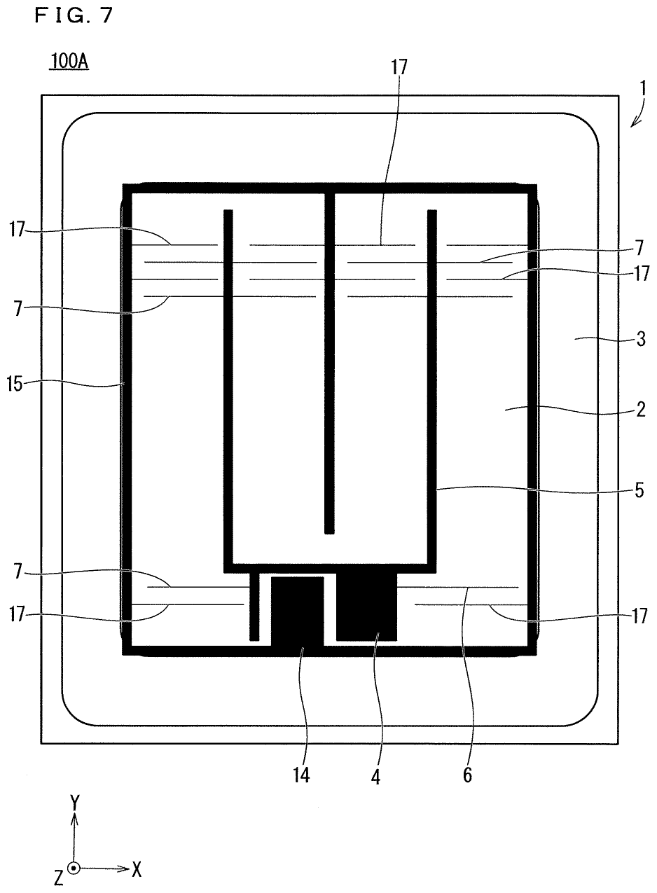

Next, a modification of the second preferred embodiment will be described. FIG. 7 is a schematic top view of the semiconductor device 100A according to a modification of the second preferred embodiment.

As illustrated in FIG. 7, the first gate wiring 5 is divided from the first gate pad 4 into two directions of the X direction and the −X direction, and then extends in the Y direction. That is, the first gate wiring 5 has a portion divided from the first gate pad 4 in the X direction and a portion divided from the first gate pad 4 in the −X direction. The second gate wiring 15 is connected to the second gate pad 14 and extends along a boundary between the active region 2 and the termination region 3. Further, the second gate wiring 15 has a portion extending in the −Y direction from the side in the Y direction of the active region 2 between the portion divided from the first gate pad 4 in the X direction and the portion divided from the first gate pad 4 in the −X direction.

Here, also in the modification of the second preferred embodiment, the interval A1, the interval A2, the interval B1, and the interval C1 are 10 μm or more.

Next, functions and effects of the second preferred embodiment and the modification thereof will be described. In the second preferred embodiment and the modification thereof, provided are the semiconductor substrate 1 in which the active region 2 in which the semiconductor element is formed, the active region having the quadrangular shape in the top view, and the termination region 3 which is the region outside the active region 2 are defined; the first gate pad 4 arranged at the center of the side in the-Y direction of the active region 2; the first gate wiring 5 connected to the first gate pad 4 and having a portion extending in the Y-axis direction; the first gate signal lines 6 and 7 connected to the first gate pad 4 or the first gate wiring 5 and extending in the X-axis direction that is the direction intersecting the Y-axis direction; the second gate pad 14 arranged at the position adjacent to the first gate pad 4 at the center of the side in the −Y direction of the active region 2; the second gate wiring 15 connected to the second gate pad 14 and having the portion extending in the Y-axis direction; and the second gate signal line 17 connected to the second gate wiring 15 and extending in the X-axis direction. The second gate wiring 15 extends along the boundary between the active region 2 and the termination region 3. A portion of the first gate wiring 5 partially surrounds the outer periphery of the second gate pad 14.

Therefore, as in the first preferred embodiment, an effective region of the semiconductor device 100A is expanded. Since the effective region of the semiconductor device 100A is expanded, a conduction voltage of the semiconductor element at the same output current decreases, and a conduction loss can be reduced.

Further, in the semiconductor device 100A according to the second preferred embodiment, the first gate pad 4 is arranged at the center of the side in the −Y direction of the active region 2 and the second gate pad 14 is arranged at the position adjacent to the first gate pad 4 at the center of the side in the −Y direction of the active region 2 as illustrated in FIGS. 5 and 7. Thus, lengths of the first and second gate signal lines 6, 7, and 17 arranged between the first and second gate pads 4 and 14, and the second gate wiring 15 are shorter than those in a case where the first and second gate signal lines 6, 7, and 17 extend from one end to the other end of the active region 2 in the X-axis direction. As a result, gate resistances of the first and second gate signal lines 6, 7, and 17 decrease, and it is possible to reduce delays of gate signals from the first and second gate pads 4 and 14 to ends of the first and second gate signal lines 6, 7, and 17. With this configuration, it is possible to reduce not only a delay difference in the same gate signal line but also a delay difference between the first gate signal lines 6 and 7, and the second gate signal line 17.

Next, an effect of suppressing interference between gate signals will be described. In a case where different gate signals are input to the first gate pad 4 and the second gate pad 14, when the interval between the first and second gate pads 4 and 14 and the interval between the first and second gate wirings 5 and 15 are too short, there is a possibility that interference between the gate signals occurs due to parasitic capacitance of an interlayer film between the first and second gate wirings 5 and 15. When the interference between the gate signals occurs, there is a possibility that the semiconductor element malfunctions and the semiconductor element is broken.

As illustrated in FIG. 6, in the semiconductor device 100A according to the second preferred embodiment and the modification thereof, the interval A1 between the first gate pad 4 and the second gate pad 14, the interval A2 between the first gate pad 4 and the second gate wiring 15, the interval B1 between the second gate pad 14 and the first gate wiring 5, and the interval C1 between the first gate wiring 5 and the second gate wiring 15 are all 10 μm or more, so that the interference between the gate signals can be suppressed. Note that the first preferred embodiment has the similar configuration so that the similar effect can be obtained.

Note that each of the preferred embodiments can be freely combined, and each of the preferred embodiments can be appropriately modified or omitted.

Hereinafter, various aspects of the present disclosure will be collectively described as appendixes.

### Appendix 1

A semiconductor device comprising:
a semiconductor substrate in which an active region in which a semiconductor element is formed, the active region having a quadrangular shape in a top view, and a termination region, which is a region outside the active region, are defined;
a first gate pad arranged at a center of a first side of the active region;
a first gate wiring connected to the first gate pad and extending in a first direction;
a first gate signal line connected to the first gate pad or the first gate wiring and extending in a second direction that is a direction intersecting the first direction;
a second gate pad arranged at a corner of the first side of the active region;
a second gate wiring connected to the second gate pad and having a portion extending in the first direction; and
a second gate signal line connected to the second gate pad or the second gate wiring and extending in the second direction,
wherein the second gate wiring extends along a boundary between the active region and the termination region.

### Appendix 2

A semiconductor device comprising:
a semiconductor substrate in which an active region in which a semiconductor element is formed, the active region having a quadrangular shape in a top view, and a termination region, which is a region outside the active region, are defined;
a first gate pad arranged at a center of a first side of the active region;
a first gate wiring connected to the first gate pad and having a portion extending in a first direction;
a first gate signal line connected to the first gate pad or the first gate wiring and extending in a second direction that is a direction intersecting the first direction;
a second gate pad arranged at a position adjacent to the first gate pad at the center of the first side of the active region;
a second gate wiring connected to the second gate pad and having a portion extending in the first direction; and
a second gate signal line connected to the second gate wiring and extending in the second direction,
wherein the second gate wiring extends along a boundary between the active region and the termination region, and
a portion of the first gate wiring partially surrounds an outer periphery of the second gate pad.

### Appendix 3

The semiconductor device according to Appendix 1 or 2, wherein the first gate signal line and the second gate signal line are alternately arranged in the first direction.

### Appendix 4

The semiconductor device according to Appendix 3, further comprising a dummy gate signal line arranged between the first gate signal line and the second gate signal line.

### Appendix 5

The semiconductor device according to any one of Appendixes 1 to 4, wherein an interval between the first gate pad and the second gate pad, an interval between the first gate pad and the second gate wiring, an interval between the second gate pad and the first gate wiring, and an interval between the first gate wiring and the second gate wiring are all 10 μm or more.

### Appendix 6

The semiconductor device according to any one of Appendixes 1 to 5, wherein all of the first gate pad, the first gate wiring, the second gate pad, and the second gate wiring include a polysilicon thin film and a metal thin film.

### Appendix 7

The semiconductor device according to any one of Appendixes 1 to 6, further comprising gate resistors built in between the first gate pad and the first gate wiring and between the second gate pad and the second gate wiring, respectively.

### Appendix 8

The semiconductor device according to Appendix 4, further comprising a trench formed in the active region, wherein each of the first gate signal line, the second gate signal line, and the dummy gate signal line is embedded in the trench and includes a polysilicon thin film.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate in which an active region in which a semiconductor element is formed, the active region having a quadrangular shape in a top view, and a termination region, which is a region outside the active region, are defined;
a first gate pad arranged at a center of a first side of the active region;
a first gate wiring connected to the first gate pad and extending in a first direction;
a first gate signal line connected to the first gate pad or the first gate wiring and extending in a second direction that is a direction intersecting the first direction;
a second gate pad arranged at a corner of the first side of the active region;
a second gate wiring connected to the second gate pad and having a portion extending in the first direction; and
a second gate signal line connected to the second gate pad or the second gate wiring and extending in the second direction,
wherein the second gate wiring extends along a boundary between the active region and the termination region.

2. A semiconductor device comprising:
a semiconductor substrate in which an active region in which a semiconductor element is formed, the active region having a quadrangular shape in a top view, and a termination region, which is a region outside the active region, are defined;
a first gate pad arranged at a center of a first side of the active region;
a first gate wiring connected to the first gate pad and having a portion extending in a first direction;
a first gate signal line connected to the first gate pad or the first gate wiring and extending in a second direction that is a direction intersecting the first direction;
a second gate pad arranged at a position adjacent to the first gate pad at the center of the first side of the active region;
a second gate wiring connected to the second gate pad and having a portion extending in the first direction; and
a second gate signal line connected to the second gate wiring and extending in the second direction,
wherein the second gate wiring extends along a boundary between the active region and the termination region, and
a portion of the first gate wiring partially surrounds an outer periphery of the second gate pad.

3. The semiconductor device according to claim 1, wherein the first gate signal line and the second gate signal line are alternately arranged in the first direction.

4. The semiconductor device according to claim 2, wherein the first gate signal line and the second gate signal line are alternately arranged in the first direction.

5. The semiconductor device according to claim 3, further comprising a dummy gate signal line arranged between the first gate signal line and the second gate signal line.

6. The semiconductor device according to claim 4, further comprising a dummy gate signal line arranged between the first gate signal line and the second gate signal line.

7. The semiconductor device according to claim 1, wherein an interval between the first gate pad and the second gate pad, an interval between the first gate pad and the second gate wiring, an interval between the second gate pad and the first gate wiring, and an interval between the first gate wiring and the second gate wiring are all 10 μm or more.

8. The semiconductor device according to claim 2, wherein an interval between the first gate pad and the second gate pad, an interval between the first gate pad and the second gate wiring, an interval between the second gate pad and the first gate wiring, and an interval between the first gate wiring and the second gate wiring are all 10 μm or more.

9. The semiconductor device according to claim 1, wherein all of the first gate pad, the first gate wiring, the second gate pad, and the second gate wiring include a polysilicon thin film and a metal thin film.

10. The semiconductor device according to claim 2, wherein all of the first gate pad, the first gate wiring, the second gate pad, and the second gate wiring include a polysilicon thin film and a metal thin film.

11. The semiconductor device according to claim 1, further comprising gate resistors built in between the first gate pad and the first gate wiring and between the second gate pad and the second gate wiring, respectively.

12. The semiconductor device according to claim 2, further comprising gate resistors built in between the first gate pad and the first gate wiring and between the second gate pad and the second gate wiring, respectively.

13. The semiconductor device according to claim 5, further comprising a trench formed in the active region, wherein each of the first gate signal line, the second gate signal line, and the dummy gate signal line is embedded in the trench and includes a polysilicon thin film.

14. The semiconductor device according to claim 6, further comprising a trench formed in the active region, wherein each of the first gate signal line, the second gate signal line, and the dummy gate signal line is embedded in the trench and includes a polysilicon thin film.
